(19) United States
(12) Patent Application Publication
(10) Pub. No.: US 2006/0023274 A1
(43) Pub. Date: Feb. 2, 2006

(54) Electronic photo display devices

(75) Inventor: Tzu-Pei Chen, Taipei (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: VIA Technologies Inc.

(21) Appl. No.: 11/086,896

(22) Filed: Mar. 22, 2005

(30) Foreign Application Priority Data
Jul. 27, 2004 (TW) 93122397

(51) Int. Cl. G03F 3/10

(52) U.S. Cl. 358/527

(57) ABSTRACT

An electronic photo display device. The device comprises a panel, which is the size of a typical photo, an internal storage medium storing digital image files, and a central control unit. The central control unit acquires a digital image from the internal storage medium and displaying it on the panel according to a control command.

### BACKGROUND

The invention relates to display devices, especially to electronic photo display devices.

Conventionally, photos are collected using photo albums, which may be damaged or decay over time. Additionally, it is inconvenient to replace photos in a photo album.

Photos can be converted to digital images using computer scanning. Digital images can also be produced using digital cameras and browsed using computer devices. Digital images can be permanently preserved and protected but can only be browsed when a computer device is activated if prints are not made.

Thus, an efficient digital images browsing method is desirable.

### SUMMARY

Electronic photo display devices are provided, enabling rapid and convenient photo browsing and providing different transmission interfaces for acquisition of digital images from different storage media. The electronic photo frame comprises a panel with photo size, an internal storage medium storing digital image files, and a central control unit. The central control unit acquires a digital image from the internal storage medium and displays it in the panel according to a control command.

### BRIEF DESCRIPTION OF THE DRAWINGS

Electronic photo display devices can be more fully understood by reading the subsequent detailed description and examples with references made to the accompanying drawings, wherein:

FIG. 1 is a schematic diagram of an embodiment of an electronic photo display device;

FIG. 2 is a block diagram of an embodiment of an electronic photo display device; and

FIG. 3 is a flowchart of an embodiment of a method for displaying digital images.

### DETAILED DESCRIPTION

Embodiments of the invention disclose an electronic photo display device and a method for displaying digital images.

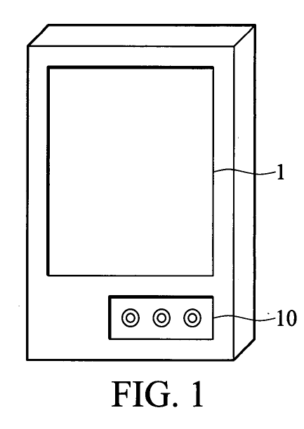

FIG. 1 is a schematic diagram of an embodiment of an electronic photo display device.

Photo display device 1 comprises an input device 10 having one or several buttons, disposed at any location on photo display device 1. A digital image can be acquired from a storage medium (not shown) using input device 10 for display on a panel of photo display device 1. Additionally, another digital image can be acquired from a storage medium (not shown) using input device 10 to intermittently replace the currently displayed digital image on the panel of photo display device 1.

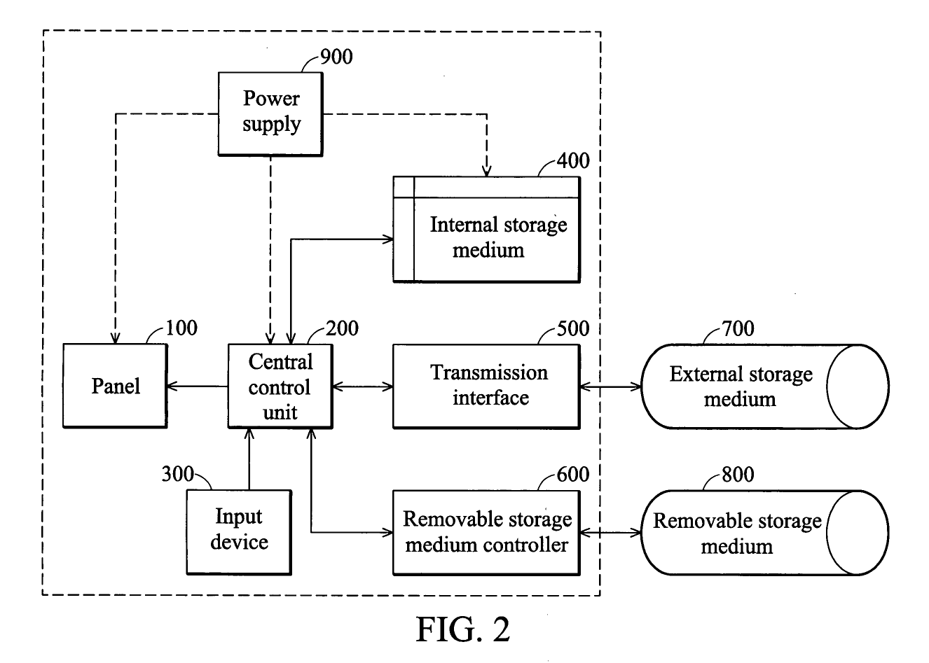

FIG. 2 is a block diagram of electronic photo display device 1, comprising a panel 100, a central control unit 200, an input device 300, an internal storage medium 400, a transmission interface 500, and a removable storage medium controller 600.

Panel 100, which is the size of a typical photo displays digital images, is a general display panel or touch panel. Internal storage medium 400, storing digital images and an operating system, fixedly disposed in the photo display device 1 is a hard disk drive complying with Advanced Technology Attachment (ATA) standards and supporting a hot swap function. Transmission interface 500 complying with Universal Serial Bus (USB) protocol, Institute of Electrical and Electronic Engineers (IEEE) protocol, or Serial Advanced Technology Attachment (SATA) technology, connects an external storage medium 700, such as an external hard disk drive. Removable storage medium controller 600 connects a removable storage medium 800, such as a compact flash (CF) card, media card (MMC), memory stick (MS) card, smart media (SM) card, or xD-picture (XD) card.

Central control unit 200 can acquire a digital image from internal storage medium 400 and display it on panel 100 according to a control command. Central control unit 200 can acquire a digital image from external storage medium 700 through transmission interface 500 and display it on panel 100 according to a control command. Central control unit 200 can acquire a digital image from removable storage medium 800 through removable storage medium controller 600 and display it on panel 100 according to a control command.

Additionally, central control unit 200 can further acquire another digital image from the described storage media to intermittently replace the currently displayed digital image on the panel 100.

Input device 300, for example, comprises several control buttons (not shown), and, when one button is pressed, input device 300 sends a control command to central control unit 200, and central control unit 200 acquires a digital image from internal storage medium 400, transmission interface 500, or removable storage medium controller 600, and displays it on panel 100. Further, when another button is pressed, input device 300 sends a control command to central control unit 200 for activating a time display function, and the central control unit 200 sequentially acquires and displays digital images from a currently selected storage medium. Image display rules are predetermined.

Additionally, image display rules can also be determined through panel 100. When one control button of input device 300 is pressed, the operating system stored in internal storage medium 400 shows a menu for determining image display methods, comprising designation display, time display, and random display, not illustrated in this embodiment of the invention.

Electronic photo display device 1 further comprises a power supply 900, an independent system power supply, supplying power to internal components thereof and external components connected6 thereto.

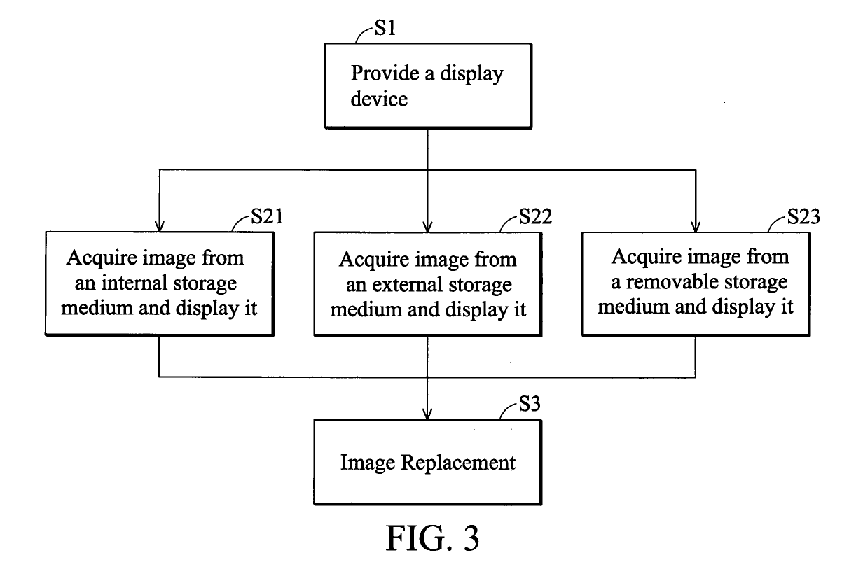

FIG. 3 is a flowchart of an embodiment of a method for displaying digital images.

An electronic photo display device, comprising a panel, an input device, an internal storage medium, a transmission interface, and a removable storage medium controller, is provided (step S1). Display images comprises the following processes. A digital image is acquired from the internal storage medium and displayed on the panel according to a control command sent by the input device (step S21). A digital image is acquired from an external storage medium through the transmission interface and displayed on the panel according to a control command sent by the input device (step S22). A digital image is acquired from a removable storage medium through the removable storage medium controller and displayed on the panel according to a control command sent by the input device (step S23).

Next, another digital image is acquired from the described storage media to intermittently replace the currently displayed digital image on the panel (step S3).

Embodiments of the invention enable rapid and convenient photo browsing and provide different transmission interfaces for acquisition of digital images from different storage media.

Although the present invention has been described in preferred embodiments, it is not intended to limit the invention thereto. Those who are skilled in this technology can still make various alterations and modifications without departing from the scope and spirit of this invention. Therefore, the scope of the present invention shall be defined and protected by the following claims and their equivalents.

What is claimed is:

1. An electronic photo display device, comprising:
a panel, which displaying digital images;
an internal storage medium, storing the digital images; and
a central control unit, coupled to the panel and internal storage medium, acquiring a digital image from the internal storage medium and displaying it on the panel according to a control command.

2. The electronic %photo frame as claimed in claim 1, wherein the panel is the size of a typical photo.

3. The electronic photo frame as claimed in claim 1, further comprising a transmission interface for connecting an external storage medium.

4. The electronic photo frame as claimed in claim 3, wherein the central control unit further acquires a digital image from the external storage medium through the transmission interface and displays it on the panel according to a control command.

5. The electronic photo frame as claimed in claim 4, wherein the central control unit further acquires another digital image from the internal or external storage medium to intermittently replace the currently displayed digital image on the panel.

6. The electronic photo frame as claimed in claim 3, wherein the transmission interface complies with Universal Serial Bus (USB) protocol, Institute of Electrical and Electronic Engineers (IEEE) protocol, or Serial Advanced Technology Attachment (SATA) technology.

7. The electronic photo frame as claimed in claim 1, further comprising a removable storage medium controller for connecting a removable storage medium.

8. The electronic photo frame as claimed in claim 7, wherein the central control unit further acquires a digital image from the removable storage medium through the removable storage medium controller and displays it on the panel according to a control command.

9. The electronic photo frame as claimed in claim 8, wherein the central control unit further acquires another digital image from the internal or removable storage medium to intermittently replace the currently displayed digital image on the panel.

10. The electronic photo frame as claimed in claim 7, wherein the removable storage medium is a compact flash (CF) card, media card (MMC), memory stick (MS) card, smart media (SM) card, or xD-picture (XD) card.

11. The electronic photo frame as claimed in claim 1, wherein the internal storage medium is a hard disk drive supporting a hot swap function.

12. The electronic photo frame as claimed in claim 1, further comprising a power supply for supplying power to the panel, internal storage medium, and central control unit.
